(19) United States
(12) Patent Application Publication
(10) Pub. No.: US 2026/0104214 A1
(43) Pub. Date: Apr. 16, 2026

(54) LOW HEAT LOSS LATENT HEAT BATTERY

(71) Applicant: The Regents of the University of California, Oakland, CA (US)

(72) Inventors: Jerry M. Woodall, Davis, CA (US); Majdi Abou Najm, Davis, CA (US)

(73) Assignee: The Regents of the University of California, Oakland, CA (US)

(21) Appl. No.: 19/115,947

(22) PCT Filed: Oct. 2, 2023
(86) PCT No.: PCT/US2023/075680

§ 371 Date: Mar. 27, 2025

Related U.S. Application Data
(60) Provisional application No. 63/413,052, filed on Oct. 4, 2022.

(51) Int. Cl. F28D 20/02; H10N 10/13

(52) U.S. Cl. CPC F28D 20/02; H10N 10/13

(57) ABSTRACT

A latent heat battery (LHB) is provided that stores latent heat for on-demand use (e.g., for conversion into electricity) and that cycles through charge and discharge cycles. In the charge cycle, a phase change material or PCM (e.g., silver) residing in an inner chamber of the battery is heated to or beyond its melting temperature, thereby storing latent heat within the battery. Illustratively, the heating may occur by collecting or focusing solar energy, or by powering an internal heater (e.g., a resistance heater). In the discharge cycle, the stored latent heat is extracted as the PCM freezes, through a heat pipe or some other construct that couples the PCM to the environment external to the LHB.

### RELATED APPLICATION(S)

This application claims the benefit of U.S. Provisional Ser. No. 63/413,052, filed 4 Oct., 2022 (docket number UC22-612-1PSP), the contents of which are incorporated by reference herein.

### BACKGROUND

This disclosure relates to the fields of electrical engineering and thermodynamics. More particularly, a latent heat battery featuring low heat loss is provided.

Latent heat batteries have been developed to store energy in the form of heat, which can be extracted as heat power or converted to another form (e.g., electricity) upon demand. However, existing schemes for storing thermal energy suffer from relatively high heat loss, which decreases the amount of time the energy can be stored and/or the amount of power that can be extracted later. The less power that can be retrieved from a latent heat battery, the lower its usefulness and efficiency.

Therefore, there remains a need for an apparatus that enables a latent heat battery to reduce the loss of thermal energy.

### SUMMARY

In some embodiments, a latent heat battery features a vacuum-insulated container that retards the loss of stored thermal energy. When and as needed, the thermal energy may be released as thermal power for use and/or for conversion to another form (e.g., electricity). The container may comprise multiple walls (e.g., an inner wall and an outer wall) that are at least partially constructed with a corrosion-resistant metal (e.g., stainless steel). In some implementations, an inner wall is at least partially composed of a high-temperature ceramic material (e.g., alumina) or fused silica or quartz.

The interior surface of the innermost wall will be in contact with the stored thermal energy (e.g., in the form of melted aluminum-silicon (AlSi) or other suitable latent heat material), while the outer surface of the outermost wall is in contact with the ambient environment. Walls are separated by a vacuum or evacuated space, and may be welded or brazed for mechanical stability at key locations.

In some implementations of these embodiments, the exterior of a top or bottom of an inner wall is coupled to an external thermoelectric generator (TEG) for generating electricity from heat withdrawn from the stored thermal energy.

In some embodiments, surfaces of one or more walls (e.g., an outer surface of the innermost wall, the inner surface of the outermost wall) are coated with a material that features low emissivity(s) and high temperature stability (e.g., silver (Ag) and/or that reflects radiant heat). Although the inner surface of the innermost wall may be at or near the melting point of the latent heat material, thermal loss to the next wall will be low due to the vacuum/evacuated space and the low-& coating. This coating, acting in concert with the vacuum, minimizes conductive, convective, and radiant thermal energy loss.

In some embodiments, the latent heat material is melted (e.g., at 577° C. for the eutectic AlSi alloy) using direct, concentrated solar radiation, either within a specialized container provided herein, or external to the container after which it is stored in the container. Alternatively, a different power source (e.g., local utility, wind turbine(s), hydroelectricity, photovoltaic cells) may be used to melt the material and thereby ‘charge’ the latent heat battery. A physical connection between a thermoelectric generator and the material (or a portion of the container surrounding the material), allows the generator to convert the thermal energy of the material into electrical power.

A latent heat battery provided herein may be portable, thereby allowing electricity to be supplied wherever needed. The energy density of an illustrative latent heat material (i.e., AlSi) is approximately 154 watt-hours/kilogram (Wh/kg).

In different embodiments, a latent heat battery may be used to power a thermoelectric generator (e.g., to yield electrical power) or some other thermal load. Other illustrative thermal loads include a heat engine (e.g., a Stirling engine); a water heater; a heat distributor (e.g., a furnace, blower, or other means of distributing heat within a closed or semi-closed area); an oven, stove or other food-preparation device; a drying device (e.g., for drying agricultural products, clothes, and/or other items); an absorption heat pump or air-conditioning system; etc.

### DESCRIPTION OF THE FIGURES

FIG. 1 is a diagram of a latent heat battery according to some embodiments.

FIG. 2A is a diagram of another latent heat battery according to some embodiments.

FIG. 2B illustrates a coating that may be applied to a wall of a latent heat battery according to some embodiments.

FIG. 3 is a flow chart illustrating a method of using a latent heat batter, in accordance with some embodiments.

### DETAILED DESCRIPTION

The following description is presented to enable any person skilled in the art to make and use the disclosed embodiments, and is provided in the context of one or more practical applications and their requirements. Various modifications to the disclosed embodiments will be readily apparent to those skilled in the art, and the general principles defined herein may be applied to other embodiments and applications without departing from the scope of those that are disclosed. Thus, the present invention or inventions are not intended to be limited to the embodiments shown, but rather are to be accorded the widest scope consistent with the disclosure.

In some embodiments, renewable soft energy is provided in the form of a latent heat battery (LHB) featuring lower heat loss as compared to previous latent heat batteries. A LHB stores energy (heat) in a material that melts as it absorbs the energy and freezes as it releases the energy. Latent heat batteries therefore differ from sensible heat batteries (SHB) in which heat is stored in a material that does not melt during absorption or freeze during discharge.

In some implementations, an abundant and relatively cheap phase-change material (PCM), such as aluminum silicon (AlSi), is cyclically melted using a renewable source (e.g., solar power, electricity generated by solar or wind power), which charges the battery, and freezes as heat is extracted to operate a Stirling engine, another heat engine that converts heat to electricity, or a heat load as the battery discharges. The charging portion of a cycle may therefore occur during daylight, to prepare the battery for discharging overnight to supply power to a house, another building, a machine, an appliance, etc. In other implementations, a battery may be charged at any time using a 24/7 non-renewable power source. For example, the battery may be charged from the electrical grid at night, when electricity is relatively cheap, and discharged during the day when electricity supplied by the grid is more expensive.

A latent heat battery described herein may be transportable in order to discharge and supply power in a location different from that in which it was charged. The energy density of AlSi is 0.154 kilowatt-hours/kg (kWh/kg), and because the average 2000 ft² home in the United States consumes approximately 30 kWh of energy per day, a LHB described herein that contains a volume of 0.0722 m³ of AlSi can store sufficient energy for powering this home for an entire day. A system of LHBs encompassing a cubic meter of this alloy could supply all the energy needed by the home for about 2 weeks.

In some embodiments in which the PCM that provides latent heat storage is AlSi, it comprises approximately 87.6% Al and 12.4% Si, by weight. The AlSi alloy is eutectic and melts/freezes at 577° C. (850 K), features a density of approximately 2,700 kg/m³, and yields latent heat of 154 Wh/kg.

By storing latent heat efficiently, with minimal heat loss, energy is available on demand in the form of heat and/or electricity. The battery could be charged in one location (e.g., at home) and transported to another location at which the stored energy can be used. For example, campers needing heat for cooking and/or heating a tent or other enclosure could tap the stored heat directly, and allow it to charge with solar power during the day. Similarly, an LHB aboard a recreational vehicle (RV) could be charged at an RV site for use anywhere, a restaurant could charge an LHB during daylight hours for heating a patio or other outdoor seating area at night. Advantageously, the battery can be charged using whatever power source is available—solar, wind turbine, hydroelectric, the electrical grid, etc.

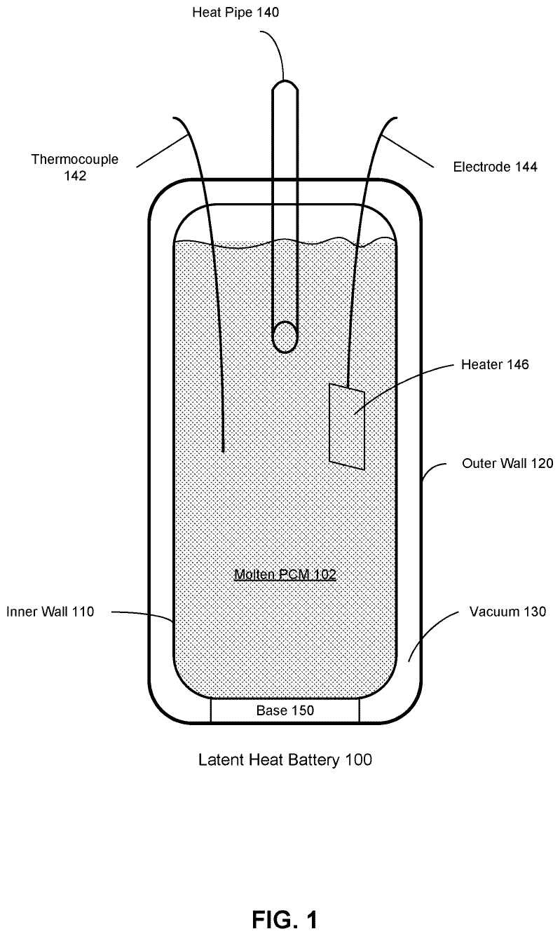

FIG. 1 is a diagram of a latent heat battery according to some embodiments. Latent heat battery 100 contains a eutectic phase-change material (PCM) 102, such as an AlSi alloy. PCM 102 is currently in a molten state after having been heated to or beyond the melting temperature (Tₘ) of the material.

PCM 102 is enclosed within inner wall or container 110 and outer wall or container 120, with the two walls separated by a vacuum. Either or both walls have cylindrical forms that are penetrated one or more times to allow insulated heat pipe 140, insulated thermocouple 142, and insulated electrode 144 (for heater 146) to contact PCM 102. Heat pipe 140 allows latent heat of PCM 102 to be extracted. More specifically, heat pipe 140 conducts heat power from molten PCM 102 toward an external Stirling engine, another mechanism for converting heat energy to a different form (e.g., electricity), or a heat load such as a stove, water heater, heating system, etc. In some implementations, the heat pipe is a solid metal (e.g., copper) rod, but may be encapsulated or coated with ceramic.

Thermocouple 142 measures and reports the temperature of the PCM. Heater 146 may be a resistive heater, a ceramic heater, or some other heater driven by renewable or non-renewable electricity and, when powered, heats PCM to or above Tₘ. Base 150, which comprises an insulative material or is hollow and contains a vacuum, supports the inner chamber formed by inner walls 110. Space within the inner chamber void that is not occupied by PCM may be occupied by an inert gas, such as nitrogen (N), to help prevent oxidation of the PCM.

One or more surfaces of walls 110, 120 are coated with low-emissivity coatings (e.g., silver) to help prevent heat loss. In particular, the outer surfaces of inner wall 110 may be coated in this manner. In combination with vacuum 130, LHB 100 can be very efficient in retaining the stored heat.

In some alternative embodiments, PCM 102 is melted using direct solar power. In these embodiments, the LHB features a window or aperture through which solar power that is being concentrated (e.g., with parabolic surfaces) shines and heats the PCM at least to Tₘ. In some implementations, the window is a heat mirror that passes solar power to the PCM and is reflective to radiant heat emitted by the hot PCM. In these implementations, after PCM 102 is melted and/or solar power is no longer available (e.g., at nighttime), the latent heat of the battery is retained.

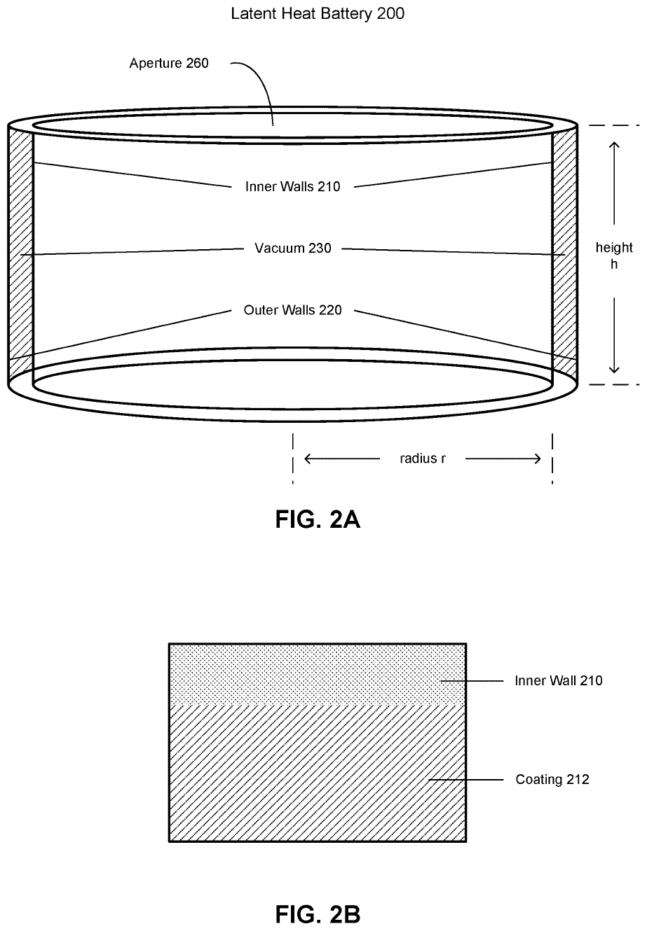

FIG. 2A is a diagram of a latent heat battery according to some embodiments. Latent heat battery 200, like LHB 100 of FIG. 1, contains a phase-change material (PCM) such as a eutectic AlSi alloy that alternately melts to store latent heat and freezes to release the latent heat. The configuration of LHB 200, however, differs in that dimensions of the battery are customized to promote heat retention.

LHB 200 is cylindrical with concentric inner and outer walls 210 and 220, respectively, again separated by a vacuum or insulator 230. However, the area of the inner surface of inner wall 210, which can be written as 2πhr (wherein h is the height and r is the radius of the inner cylinder), is twice the area of the inner surface of bottom 208, which can be written as πr². Therefore, r=h and the volume V of the cylinder is πh³.

As indicated above, 30 kWh of energy can power an average home for one day, and AlSi has a latent heat value of 0.154k Wh/kg. Thus, 195 kg (30 kWh÷0.154 kWh/kg) of molten AlSi must be stored in LHB 200 if it is to power the home for 24 hours. Because the density of AlSi is approximately 2,700 kg/m³, which equates to 2.7 kg/liter (1), the cylinder must contain a volume of 72.2 liters (195 kg÷2.7 kg/l) or 72,200 cm³ (or 0.0722 m³).

Solving V=πh³=72,200 cm³ for h, we see that h=22,982^{1/3} cm or 28.4 cm. Therefore, the radius r and height h of the cylinder are 28.4 cm, and the diameter and circumference of the bottom of the cylinder at the inner surface of inner wall 210 of LHB 200 are 56.8 cm and 178.4 cm, respectively. Moreover, the area of the bottom of the cylinder within inner wall 210 is 2,533 cm² (or 0.2533 m²), and the area of the inner surface of the inner wall is 5,066 cm² (or 0.5066 m²).

Because the PCM is metallic, it melts and freezes uniformly and maintains a substantially uniform temperature as it heats and as it cools. Therefore, as it cools, the LHB can continue providing latent heat even though the heat pipe is in contact with only a portion of the PCM. In other words, the metallic nature of the PCM ensures that latent heat remaining in the cooling PCM is conducted to the heat pipe.

LHB 200 features solar window/heat mirror 260 for admitting focused or reflected solar radiation to melt the PCM during daylight hours. Although not shown in FIG. 2A, a heat pipe may pierce the top, bottom, or a side of LHB 200 in order to extract stored heat energy.

FIG. 2B illustrates a coating applied to a wall of a latent heat battery according to some embodiments. In these embodiments, the outer surface of inner wall 210 is coated with a low emissivity coating or film such as silver (Ag), for which ε=0.02. For example, when applied to the outer surface of the inner wall, the entire surface may be coated.

In some embodiments, an inner wall of a multi-wall latent heat battery is made of a metal (e.g., stainless steel), but may feature a ceramic or glass insert or separator between the wall and the PCM. One benefit of this configuration is that the insert prevents the metal from being corroded by the PCM during repeated melt/freeze cycles. In these embodiments, the low-emissivity coating may still be applied to the outer surface of the inner wall.

As shown above in FIG. 1, in some embodiments, the LHB contains a heater, with electrodes connected to an external power source. The heater is powered during a charging phase, to melt the PCM, and turned off during a discharge phase, when a heat pipe conveys heat from the PCM to an external receiver. The heater may be coated or insulated (e.g., with ceramic) to avoid short-circuits and/or resist corrosion.

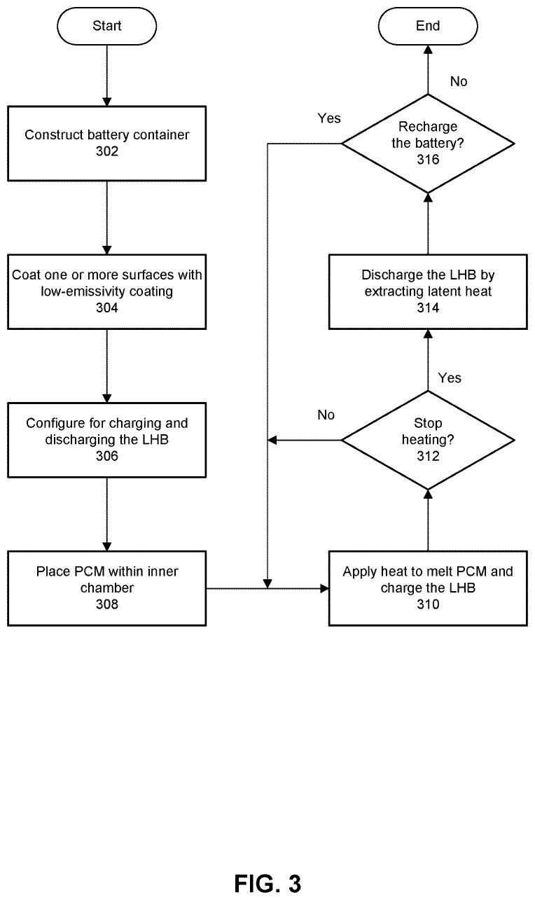

FIG. 3 is a flow chart demonstrating a method of operating a latent heat battery according to some embodiments. In one or more embodiments, one or more of the operations may be omitted, repeated, and/or performed in a different order. Accordingly, the specific arrangement of steps shown in FIG. 3 should not be construed as limiting the scope of the embodiments.

In operation 302, a container or vessel is constructed for use as a latent heat battery. The container is constructed with multiple chambers or walls, a bottom, and a top. One or more walls, especially the outer wall, may be metal (e.g., stainless steel), but one or more walls may also or instead comprise ceramic or fused quartz or silica, or may feature a ceramic or glass layer adjacent to either side of the wall. The chambers or walls may illustratively be connected to the base and/or top via welding, brazing, or some other technique.

An inner chamber, which is defined by an inner wall, the bottom, and the top, is isolated from an outer chamber (e.g., defined by an outer wall) by a vacuum. The bottom of the inner chamber may be coplanar or coterminous with the bottom of the outer chamber, or they may be distinct from each other and separated by a metal, metallic, or inert base that supports the inner chamber. Similarly, the top of the inner chamber and the top of the outer chamber may be coterminous or isolated. Thus, the LHB container may be constructed to minimize physical contact between the inner walls/chamber and the outer walls/chamber in order to limit the conductive, convective, and radiant transfer of heat away from the inner chamber.

Regardless of the configuration chosen, in these embodiments two walls (an inner wall and an outer wall) are separated by a vacuum. One or more surfaces of the inner wall are coated with a thermally low-emissivity material capable of withstanding, in a vacuum, temperatures at least equal to the melting temperature of the PCM.

In operation 304, the outer surface(s) of the inner chamber are coated with a low thermal emissivity material (e.g., Ag), and the inner surface(s) of the outer chamber may be coated with a highly reflective film or a film having low emissivity. Interior surfaces of the top of the inner chamber may also be coated with either a reflective or low-emissivity film.

In operation 306, the container is configured for charging and discharging the battery or, in other words, for supplying and extracting heat to and from a phase-change material (PCM) residing within the LHB. For heating purposes, this may involve installing a heater (e.g., a resistance heater) in the inner chamber, and leads or electrodes for supplying power to the heater (e.g., through the top(s) of the inner and outer chambers). As one alternative, the top(s) of the chambers may comprise one or more windows that occupy at least a portion of the horizontal surface area of the top(s), in order to admit solar radiation, which may be concentrated, for melting the PCM, and to reflect heat radiating from the PCM.

Operation 306 also comprises installation of a heat pipe or similar means for extracting heat from the battery. In some embodiments, a simple metal rod (e.g., copper), which may be insulated or encapsulated in ceramic or glass or other material, penetrates a surface of the container (e.g., the top, the bottom, a side). During its discharge phase, latent heat stored in the PCM is conducted to an external load for use in the same form (i.e., as heat) and/or for conversion to another form (e.g., electricity).

In operation 308, the PCM is installed in the inner chamber, in a solid state. By volume, the amount of PCM installed in the inner chamber will be less than the volume of the inner chamber, but may be approximately 85% of the chamber's volume in some implementations. The remaining volume may be fully or partially occupied with an inert gas, such as nitrogen, to resist oxidation of the PCM.

In operation 310, heat is applied to the PCM to melt it and charge the battery, or to keep the PCM in a melted or semi-melted state.

In operation 312, a decision is made whether to stop heating/melting the PCM. If, for example, the PCM is melted using direct solar power, heating will cease at nighttime. Or, if the PCM is melted using an internal heater, heating may cease when the LHB is fully charged (e.g., the PCM is uniformly melted), when the cost of electricity to supply the heater rises (e.g., during daylight hours of high electricity demand), or when it is desired to extract and use the stored latent heat. When heating is to cease, the method advances to operation 314; otherwise, it returns to operation 310.

In operation 314, the latent heat battery is partially or fully discharged while the stored heat is extracted as the PCM freezes.

In operation 316, if the LHB is to be recharged, the method returns to operation 310. Otherwise, the method ends.

An environment in which one or more embodiments described above are executed may incorporate a general-purpose computer or a special-purpose device such as a hand-held computer or communication device. Some details of such devices (e.g., processor, memory, data storage, display) may be omitted for the sake of clarity. A component such as a processor or memory to which one or more tasks or functions are attributed may be a general component temporarily configured to perform the specified task or function, or may be a specific component manufactured to perform the task or function. The term “processor” as used herein refers to one or more electronic circuits, devices, chips, processing cores and/or other components configured to process data and/or computer program code.

Data structures and program code described in this detailed description are typically stored on a non-transitory computer-readable storage medium, which may be any device or medium that can store code and/or data for use by a computer system. Non-transitory computer-readable storage media include, but are not limited to, volatile memory; non-volatile memory; electrical, magnetic, and optical storage devices such as disk drives, magnetic tape, CDs (compact discs) and DVDs (digital versatile discs or digital video discs), solid-state drives, and/or other non-transitory computer-readable media now known or later developed.

Methods and processes described in the detailed description can be embodied as code and/or data, which may be stored in a non-transitory computer-readable storage medium as described above. When a processor or computer system reads and executes the code and manipulates the data stored on the medium, the processor or computer system performs the methods and processes embodied as code and data structures and stored within the medium.

Furthermore, the methods and processes may be programmed into hardware modules such as, but not limited to, application-specific integrated circuit (ASIC) chips, field-programmable gate arrays (FPGAs), and other programmable-logic devices now known or hereafter developed. When such a hardware module is activated, it performs the methods and processes included within the module.

The foregoing embodiments have been presented for purposes of illustration and description only. They are not intended to be exhaustive or to limit this disclosure to the forms disclosed. Accordingly, many modifications and variations will be apparent to practitioners skilled in the art. The scope is defined by the appended claims, not the preceding disclosure.

1. A latent heat battery, comprising:
multiple walls, including an inner wall and an outer wall;
thermal insulation between the inner wall and the outer wall;
within the inner wall, a volume occupied by a phase-change material (PCM); and
a thermal connection between the PCM and a heat load external to the latent heat battery;
wherein one or more surfaces of the multiple walls adjacent to the thermal insulation and not in contact with the PCM are coated with a low-emissivity material.

2. (canceled)

3. The latent heat battery of claim 1, wherein the insulation comprises vacuum.

4. The latent heat battery of claim 1, wherein the inner wall comprises a ceramic material.

5. The latent heat battery of claim 1, wherein one or more of the multiple walls are composed of stainless steel.

6. The latent heat battery of claim 1, wherein the PCM is a eutectic aluminum silicon (AlSi) alloy.

7. The latent heat battery of claim 1, wherein the latent heat battery is cylindrical, the inner wall defines an inner chamber, and the outer wall defines an outer chamber.

8. The latent heat battery of claim 1, further comprising:
a resistance heater that melts the latent heat material.

9. A latent heat battery, comprising:
a cylindrical housing comprising multiple concentric walls;
a core volume located within an inner wall, wherein the core volume is at least partially occupied by a phase change material; and
a thermal connection between the phase change material and a thermal load.

10. The latent heat battery of claim 9, further comprising:
a vacuum between the inner wall and an outer wall; and
a low-emissivity coating on a surface of the inner wall not in contact with the PCM.

11. The latent heat battery of claim 9, wherein one or more of the inner wall and the outer wall are composed of a ceramic material.

12. The latent heat battery of claim 9, wherein one or more of the inner wall and the outer wall are composed of stainless steel.

13. The latent heat battery of claim 9, further comprising an aperture in a top surface of the latent heat battery, wherein the aperture comprises a transparent heat mirror.

14. The latent heat battery of claim 9, wherein the thermal load comprises one or more of:
a thermoelectric generator;
a heat engine;
a heat distributor;
a water heater;
a food-preparation device;
a drying device; and
an absorption heat pump.

15. A method of using a latent heat battery (LHB), the method comprising:
coating one or more surfaces of a multi-wall container with a low-emissivity coating;
storing a phase-change material (PCM) within a void defined by an inner wall of the LHB; and
alternately charging and discharging the LHB, wherein:
charging the LHB comprises heating the PCM to a melting temperature of the PCM; and
discharging the LHB comprises extracting latent heat from the PCM as the PCM freezes;
wherein the one or more surfaces of the multi-wall container are surfaces that are not in contact with the PCM.

16. The method of claim 15, wherein the low-emissivity coating comprises silver.

17. The method of claim 15, wherein the PCM comprises a eutectic aluminum silicon alloy.

18. The method of claim 15, wherein heating the PCM comprises powering a resistance heater located within the void.

19. The method of claim 15, wherein heating the PCM comprises focusing solar radiation on the PCM through an aperture or a window.

20. The method of claim 19, wherein the aperture or window comprises a heat mirror.

21. The method of claim 15, wherein extracting latent heat from the PCM comprises receiving heat via a heat pipe in contact with the PCM.

22. The method of claim 15, wherein said charging of the LHB uses electricity from one or more renewable sources.

23. The method of claim 15, wherein said charging of the LHB uses electricity from one or more non-renewable sources.

24. The method of claim 15, further comprising occupying a portion of the void not occupied by the PCM with an inert gas.
